(19) United States
(12) Patent Application Publication
(10) Pub. No.: US 2026/0255944 A1
(43) Pub. Date: Aug. 27, 2026

(54) SEMICONDUCTOR DEVICE

(71) Applicant: ROHM CO., LTD., Kyoto (JP)

(72) Inventor: Hiroyuki SHINKAI, Kyoto (JP)

(21) Appl. No.: 19/545,133

(22) Filed: Feb. 20, 2026

(30) Foreign Application Priority Data
Feb. 27, 2025 (JP) 2025-030682

(51) Int. Cl. H10W 20/20

(52) U.S. Cl. CPC H10W 20/211

(57) ABSTRACT

A semiconductor device includes: a conductor including a main surface facing one side in a thickness direction; and a semiconductor element located on the one side in the thickness direction relative to the conductor and supported by the main surface, wherein the semiconductor element includes: an element body that is rectangular when viewed in the thickness direction; and a plurality of first and second conductive columns each protruding from the element body to the other side in the thickness direction and bonded to the main surface, wherein the first and second conductive columns respectively include a first and a second bonding surface facing the main surface, and a first area of the first bonding surface and a second area of the second bonding surface are different, and wherein, among the plurality of first and second conductive columns, four second conductive columns are closest to four corners of the element body.

### CROSS-REFERENCE TO RELATED APPLICATION

This application is based upon and claims the benefit of priority from Japanese Patent Application No. 2025-030682, filed on February 27, 2025, the entire contents of which are incorporated herein by reference.

### TECHNICAL FIELD

The present disclosure relates to a semiconductor device.

### BACKGROUND

Various configurations have been proposed for semiconductor devices equipped with semiconductor elements. In the related art, as an example of a conventional semiconductor device, the semiconductor device includes a lead, a semiconductor element, and a sealing resin. The semiconductor element is supported by the lead. The sealing resin covers a portion of the lead and the semiconductor element.

In the semiconductor device of the related art, the semiconductor element is mounted on the lead by flip-chip mounting. The lead includes a main surface facing one side in a thickness direction. The semiconductor element includes a plurality of electrodes provided on a side opposite the main surface, and the plurality of electrodes are bonded to the main surface of the lead via a bonding layer made of, for example, solder. Each of the plurality of electrodes includes a cylindrical column protruding toward the lead. The column is formed by electroplating. The column is bonded to the lead via the bonding layer.

Different diameters of the columns may result in different thicknesses of the respective columns. If a difference occurs in the thicknesses of the columns, the semiconductor element bonded to the lead may become tilted. If the semiconductor element is placed in a tilted manner with respect to the lead, defects such as bonding failures may occur.

### BRIEF DESCRIPTION OF DRAWINGS

The accompanying drawings, which are incorporated in and constitute a part of the specification, illustrate embodiments of the present disclosure.

FIG. 1 is a perspective view showing a semiconductor device according to a first embodiment of the present disclosure.

FIG. 2 is a plan view (shown through a sealing resin) showing the semiconductor device according to the first embodiment of the present disclosure.

FIG. 3 is a plan view (shown through the sealing resin and a semiconductor element) showing the semiconductor device according to the first embodiment of the present disclosure.

FIG. 4 is a bottom view showing the semiconductor device according to the first embodiment of the present disclosure.

FIG. 5 is a front view showing the semiconductor device according to the first embodiment of the present disclosure.

FIG. 6 is a rear view showing the semiconductor device according to the first embodiment of the present disclosure.

FIG. 7 is a right side view showing the semiconductor device according to the first embodiment of the present disclosure.

FIG. 8 is a left side view showing the semiconductor device according to the first embodiment of the present disclosure.

FIG. 9 is a cross-sectional view taken along line IX-IX in FIG. 3.

FIG. 10 is a cross-sectional view taken along line X-X in FIG. 3.

FIG. 11 is a cross-sectional view taken along line XI-XI in FIG. 3.

FIG. 12 is a cross-sectional view taken along line XII-XII in FIG. 3.

FIG. 13 is a cross-sectional view taken along line XIII-XIII in FIG. 3.

FIG. 14 is an enlarged view of FIG. 10.

FIG. 15 is a partially enlarged view of FIG. 14 (near a first conductive column).

FIG. 16 is a partially enlarged view of FIG. 14 (near a second conductive column).

FIG. 17 is a partially enlarged view of FIG. 14 (near a second conductive column).

FIG. 18 is a plan view (shown through a sealing resin and a semiconductor element) showing a semiconductor device according to a second embodiment of the present disclosure.

FIG. 19 is a partially enlarged cross-sectional view showing the semiconductor device according to the second embodiment of the present disclosure.

FIG. 20 is a partially enlarged cross-sectional view taken along line XX-XX in FIG. 19.

FIG. 21 is a partial plan view (shown through a sealing resin and a semiconductor element) showing a semiconductor device according to a third embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Preferred embodiments of the present disclosure are described in detail with reference to the drawings.

In the following, same or similar components are denoted by same reference numerals, and explanation thereof will be omitted. In the present disclosure, the terms "first," "second," "third," etc. are used merely as labels and are not necessarily intended to order their objects.

In the present disclosure, the phases "a certain object A is formed in a certain object B" and "a certain object A is formed on a certain object B" include, unless otherwise specified, "a certain object A is directly formed in a certain object B" and "a certain object A is formed in a certain object B with another object interposed between the certain object A and the certain object B." Similarly, the phases "a certain object A is disposed in a certain object B" and "a certain object A is disposed on a certain object B" include, unless otherwise specified, "a certain object A is directly disposed in a certain object B" and "a certain object A is disposed in a certain object B with another object interposed between the certain object A and the certain object B." Similarly, the phase "a certain object A is located on a certain object B" includes, unless otherwise specified, "a certain thing A is located on a certain object B with the certain object A in contact with the certain object B" and "a certain object A is located on a certain object B with another object interposed between the certain object A and the certain object B." In addition, the phase "a certain object A overlaps with a certain object B when viewed in a certain direction" includes, unless otherwise specified, "a certain object A overlaps entirely with a certain object B" and "a certain object A overlaps partially with a certain object B." In addition, the phase "(a material of) a certain object A contains a certain material C" includes a case where "(a material of) a certain object A is made of a certain material C" and a case where "(a material of) a certain object A is mainly composed of a certain material C." In addition, the phase "a certain surface A faces a certain direction B (one side or the other side of the direction B)" is, unless otherwise specified, not limited to a case where an angle of the surface A with respect to the direction B is 90 degrees, and includes a case where the surface A is tilted with respect to the direction B.

### First Embodiment

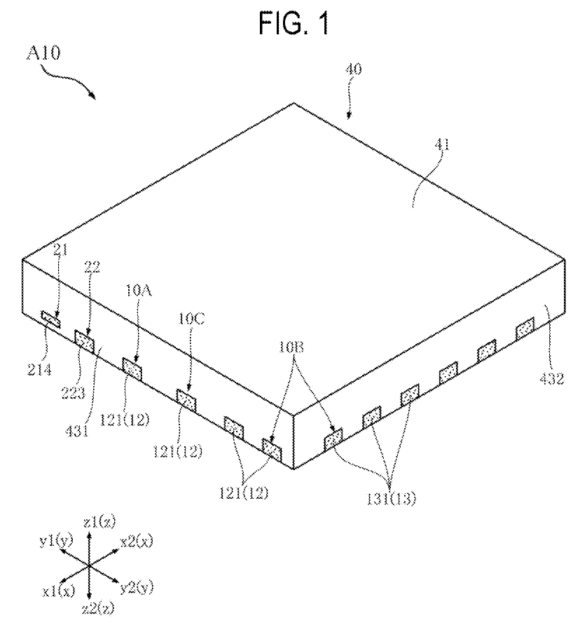

A semiconductor device according to a first embodiment of the present disclosure is described with reference to FIGS. 1 to 17. The semiconductor device A10 of this embodiment includes first leads 10A, 10B, and 10C, a plurality of second leads 21, a pair of third leads 22, a semiconductor element 3, a plurality of bonding materials 5, a plurality of metal layers 6, and a sealing resin 40. A package format of the semiconductor device A10 is not particularly limited, and in this embodiment, it is a QFN (Quad Flat Non-leaded package) type, as shown in FIG. 1. Further, applications and functions of the semiconductor device A10 are not limited in any way. The applications of the semiconductor device A10 include, for example, electronic equipment, general industrial equipment, automotive applications, and the like. The functions of the semiconductor device A10 include, for example, a DC/DC converter, an AC/DC converter, and the like. The semiconductor element 3 is a flip-chip type LSI (Large Scale Integration). The semiconductor element 3 includes therein a switching circuit 321 and a control circuit 322 (each of which is described in detail later). In the semiconductor device A10, the switching circuit 321 converts DC power (voltage) to AC power (voltage). The semiconductor device A10 is used, for example, as one component of a DC/DC converter circuit.

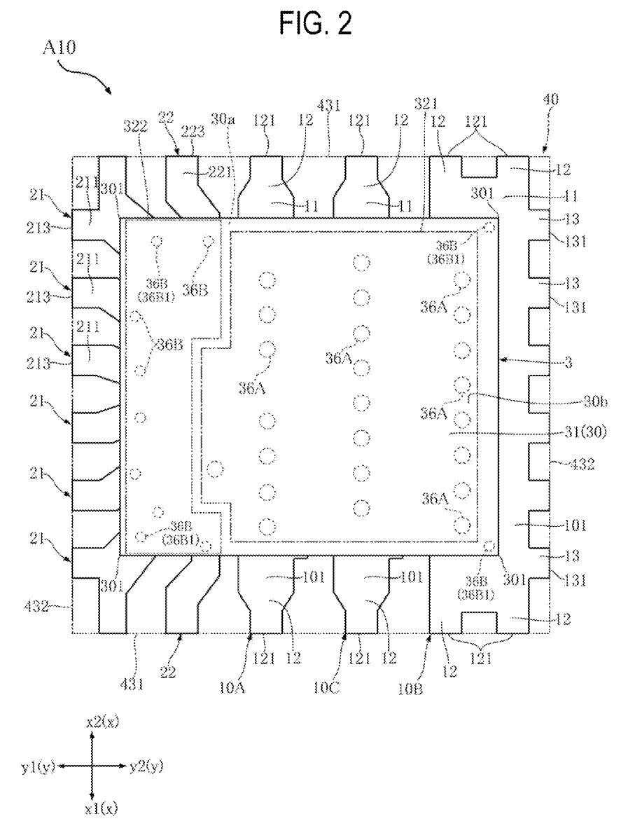

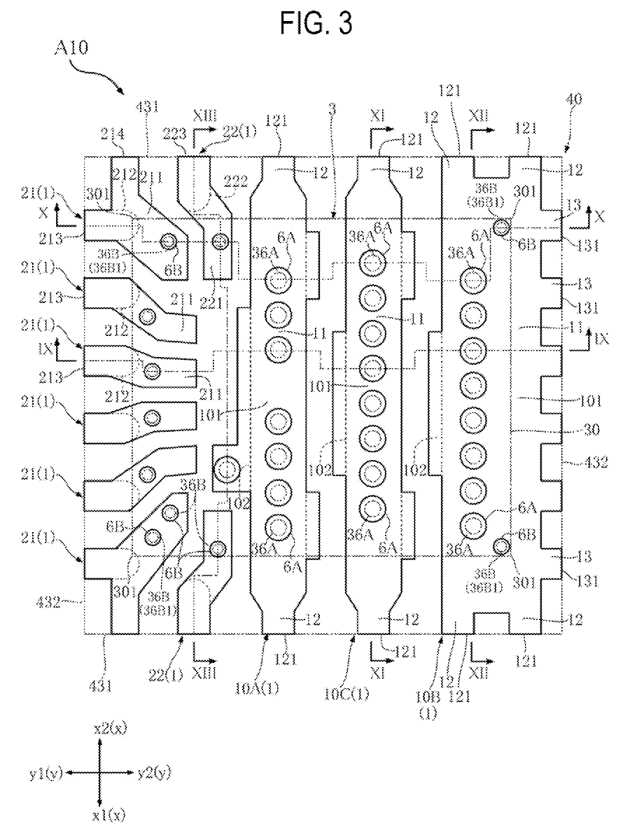

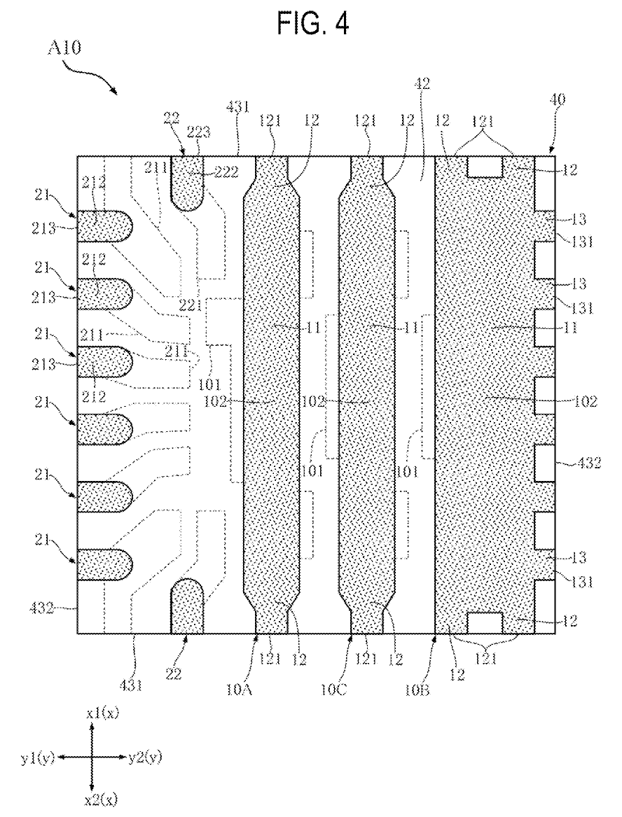

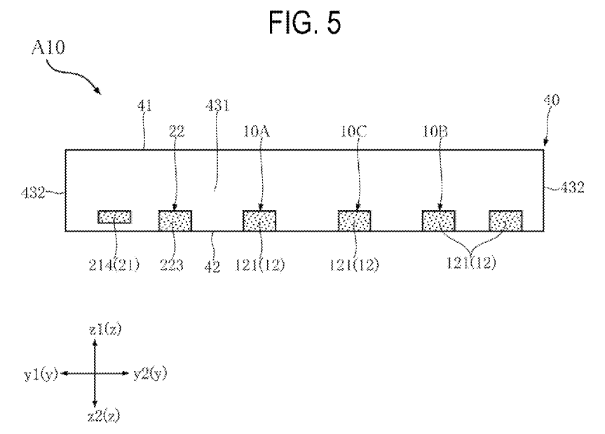

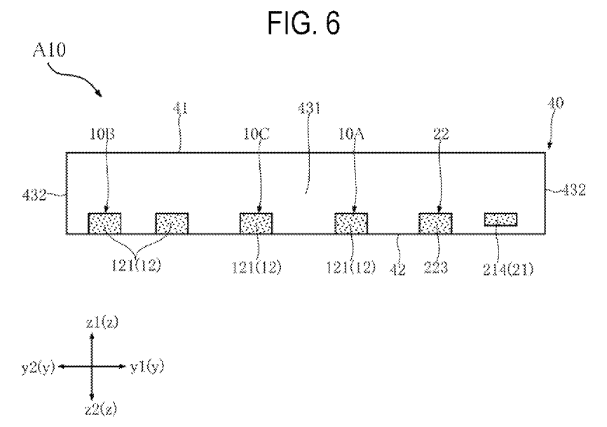

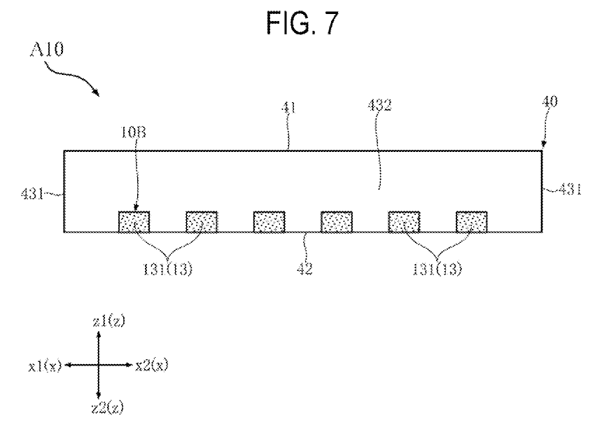

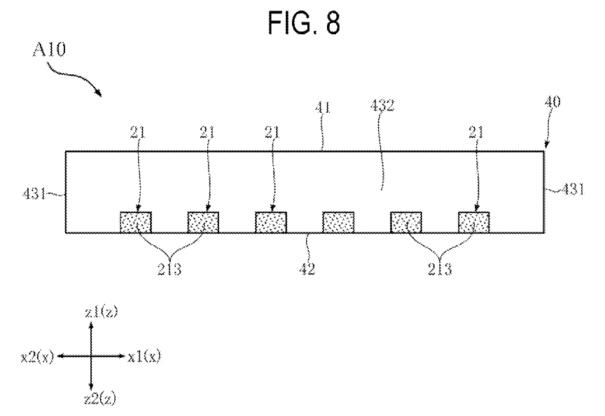

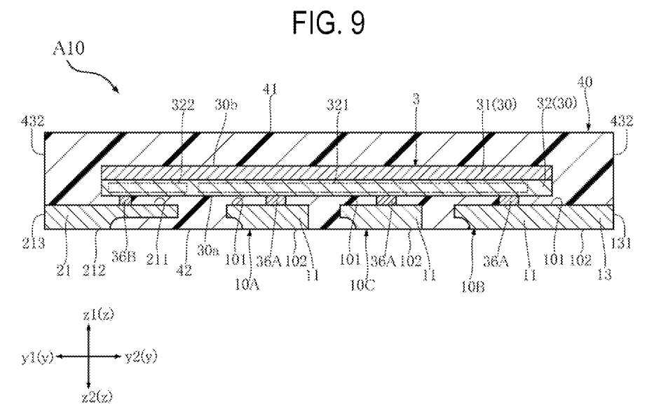

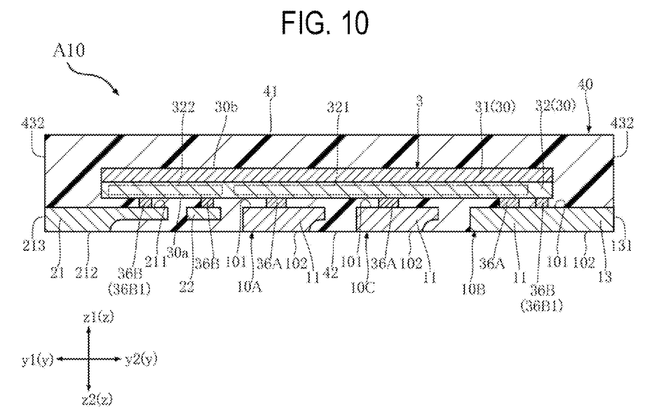

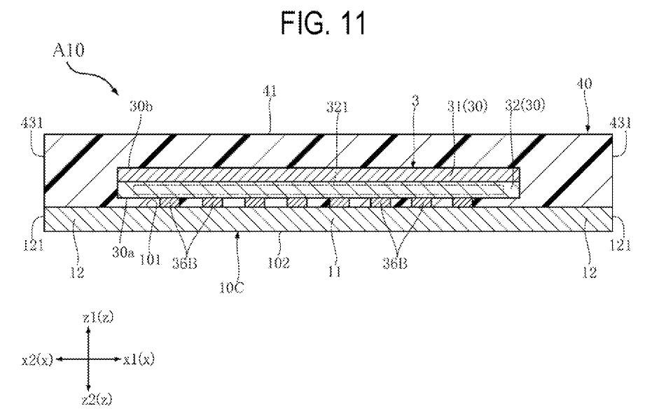

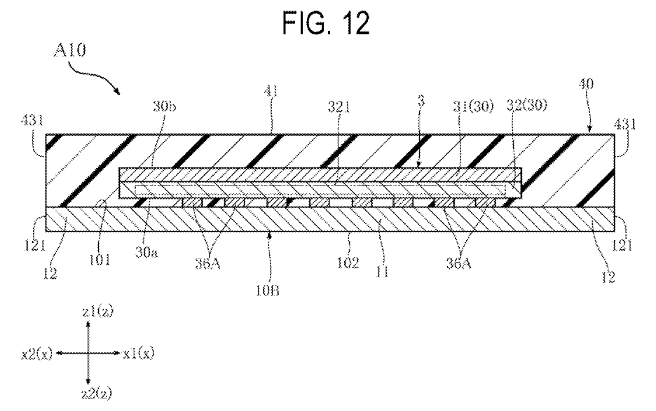

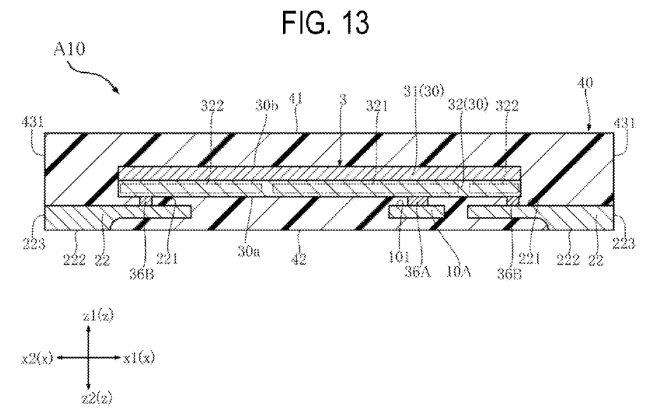

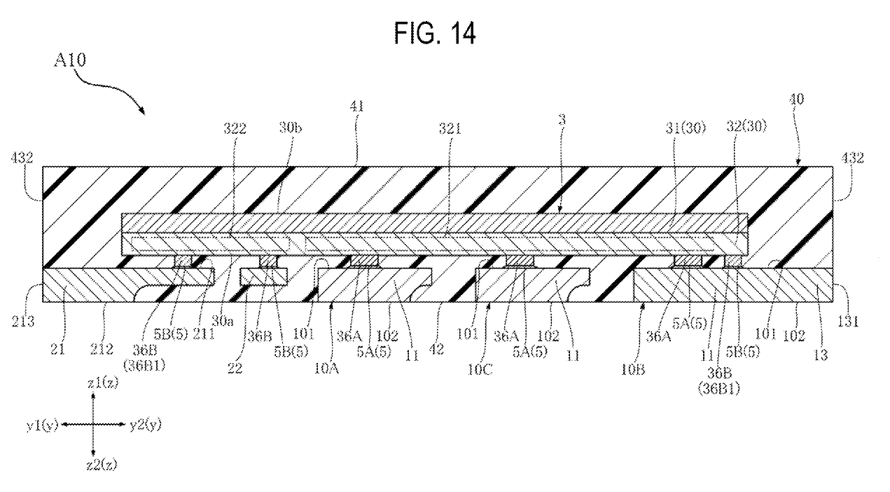

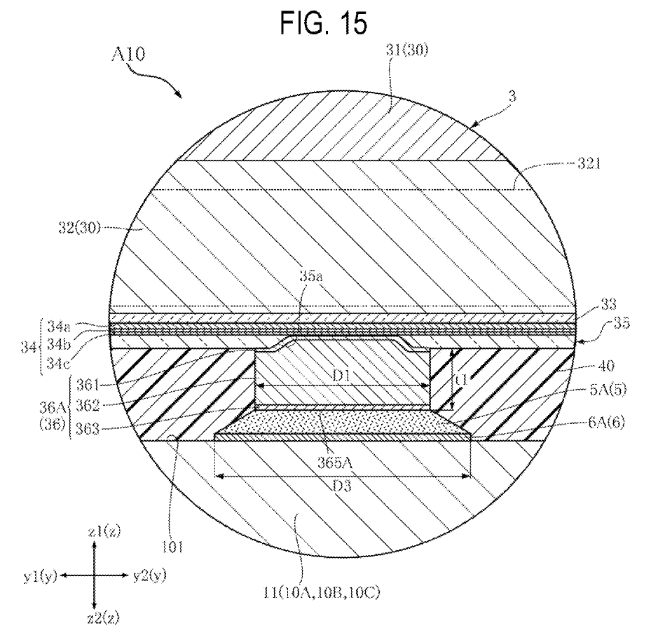

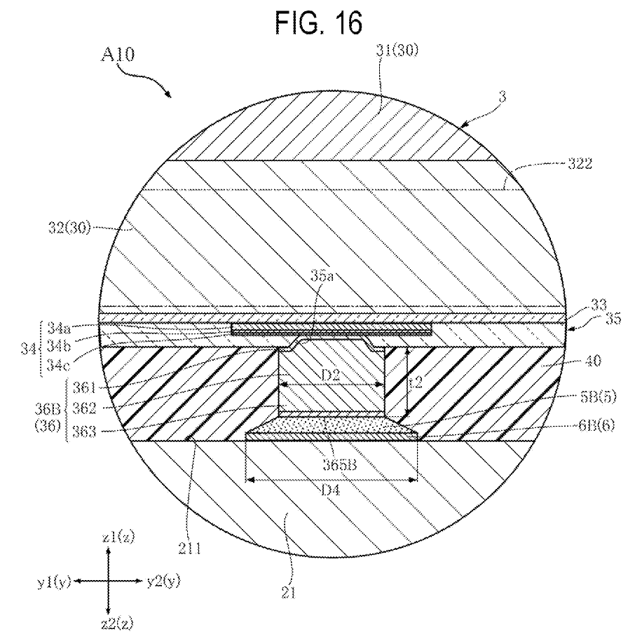

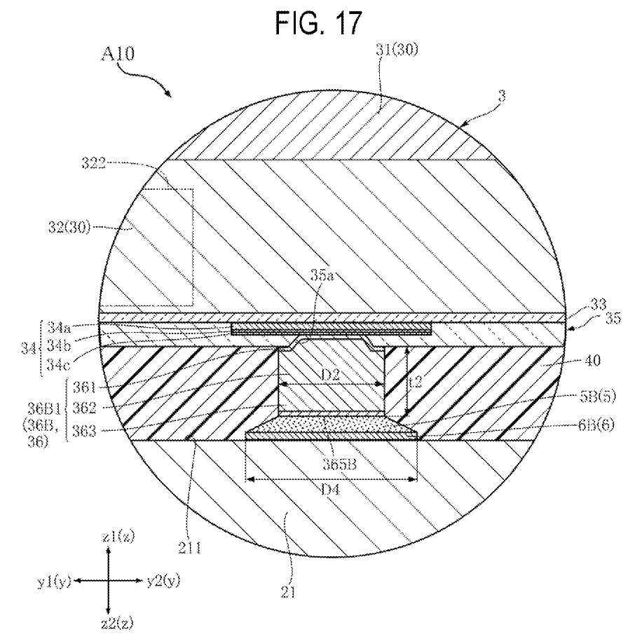

FIG. 1 is a perspective view showing the semiconductor device A10. FIG. 2 is a plan view showing the semiconductor device A10. In FIG. 2, for ease of understanding, the sealing resin 40 is shown through and an outline of the sealing resin 40 is indicated by an imaginary line (two-dot chain line). FIG. 3 is a plan view showing the semiconductor device A10. In FIG. 3, for ease of understanding, the sealing resin 40 and the semiconductor element 3 are shown through and the sealing resin 40 and the semiconductor element 3 are indicated by imaginary lines (two-dot chain lines). FIG. 4 is a bottom view showing the semiconductor device A10. FIG. 5 is a front view showing the semiconductor device A10. FIG. 6 is a rear view showing the semiconductor device A10. FIG. 7 is a right side view showing the semiconductor device A10. FIG. 8 is a left side view showing the semiconductor device A10. FIG. 9 is a cross-sectional view taken along line IX-IX in FIG. 3 . FIG. 10 is a cross-sectional view taken along line X-X in FIG. 3. FIG. 11 is a cross-sectional view taken along line XI-XI in FIG. 3. FIG. 12 is a cross-sectional view taken along line XII-XII in FIG. 3. FIG. 13 is a cross-sectional view taken along line XIII-XIII in FIG. 3. FIG. 14 is an enlarged view of FIG. 10. FIG. 15 is a partially enlarged view of FIG. 14 (near a first conductive column 36A to be described later). FIG. 16 is a partially enlarged view of FIG. 14 (near a second conductive column 36B to be described later). FIG. 17 is a partially enlarged view of FIG. 14 (near a corner-proximal column 36B1 to be described later).

The semiconductor device A10 is plate-shaped and has a rectangular shape when viewed in a thickness direction (plan view). In describing the semiconductor device A10, the thickness direction (plan view direction) of the semiconductor device A10 is an example of the "thickness direction" in the present disclosure and is referred to as a "thickness direction z." A direction along one side of the semiconductor device A10 that is perpendicular to the thickness direction z is referred to as a "first direction x." A direction perpendicular to both the thickness direction z and the first direction x is referred to as a "second direction y." As shown in FIGS. 1 and 2, the semiconductor device A10 is square when viewed in the thickness direction z. Further, one side in the thickness direction z corresponds to "one side in the thickness direction" in the present disclosure and is referred to as a "z1 side in the thickness direction z," while the other side in the thickness direction z corresponds to "the other side in the thickness direction" in the present disclosure and is referred to as a "z2 side in the thickness direction z." One side in the first direction x is referred to as an "x1 side in the first direction x," and the other side in the first direction x is referred to as an "x2 side in the first direction x." One side in the second direction y is referred to as a "y1 side in the second direction y," and the other side in the second direction y is referred to as a "y2 side in the second direction y." A shape and dimensions of the semiconductor device A10 are not particularly limited.

As shown in FIG. 2, the first leads 10A, 10B, and 10C, the plurality of second leads 21, and the pair of third leads 22 support the semiconductor element 3 and serve as terminals for mounting the semiconductor device A10 on a wiring board. As shown in FIGS. 9 to 13, each of the first leads 10A, 10B, and 10C, the plurality of second leads 21, and the pair of third leads 22 is partially covered with the sealing resin 40. In FIGS. 1 and 4 to 8, portions of the first leads 10A, 10B, and 10C, the plurality of second leads 21, and the pair of third leads 22 that are exposed from the sealing resin 40 are hatched with a plurality of discrete dots. Hereinafter, the first leads 10A, 10B, and 10C, the plurality of second leads 21, and the pair of third leads 22 may be collectively referred to as a "conductor 1."

The conductor 1 is formed, for example, by subjecting a metal plate to an etching process. It may also be formed by subjecting the metal plate to a punching process, a bending process, or the like. The first leads 10A, 10B, and 10C, the plurality of second leads 21, and the pair of third leads 22 are disposed to be spaced apart from one another. A constituent material of the conductor 1 is, for example, but not limited to, Cu or a Cu alloy.

As shown in FIGS. 3 and 4, each of the first leads 10A, 10B, and 10C is strip-shaped, extending in the first direction x when viewed in the thickness direction z. Each of the first leads 10A, 10B, and 10C includes a first main surface 101 and a first back surface 102 facing opposite sides in the thickness direction z. The first main surface 101 faces the z1 side in the thickness direction z and opposes the semiconductor element 3. The first main surface 101 is covered with the sealing resin 40. The first back surface 102 faces the z2 side in the thickness direction z. The first back surface 102 is exposed from the sealing resin 40. In the first leads 10A, 10B, and 10C, the semiconductor element 3 is supported by the first main surface 101. Also, as shown in FIGS. 3 and 4, in the illustrated example, an area of the first main surface 101 is larger than an area of the first back surface 102 in each of the first leads 10A, 10B, and 10C. A portion of each of the first leads 10A, 10B, and 10C where the first main surface 101 does not overlap the first back surface 102 when viewed in the thickness direction z is formed, for example, by half-etching from a first back surface 102 side. This portion prevents each of the first leads 10A, 10B, and 10C from falling off from a resin back surface 42 of the sealing resin 40 by virtue of an anchoring effect.

The first leads 10A and 10B receive DC power (voltage) to be converted in the semiconductor device A10. In this embodiment, the first lead 10A is a positive electrode (P terminal). The first lead 10B is a negative electrode (N terminal). The first lead 10C outputs AC power (voltage) that is obtained by conversion of DC power (voltage) by the switching circuit 321(to be described later) of the semiconductor element 3. As shown in FIG. 3, the first leads 10A, 10B, and 10C are arranged along the second direction y in an order of the first lead 10A, the first lead 10C, and the first lead 10B, from the y1 side toward the y2 side of the second direction y. The first lead 10A is located between the first lead 10C and the plurality of second leads 21 in the second direction y. The first lead 10C is located between the first lead 10A and the first lead 10B in the second direction y.

As shown in FIGS. 3 and 4, each of the first lead 10A and the first lead 10C includes a main portion 11 and a pair of side portions 12. The main portion 11 extends in the first direction x. The pair of side portions 12 is connected to both ends of the main portion 11 in the first direction x and have a smaller dimension in the second direction y than the main portion 11. Each of the pair of side portions 12 includes a first end surface 121. As shown in FIG. 11, the first end surface 121 is connected to both the first main surface 101 and the first back surface 102 and faces the first direction x. The first end surface 121 is exposed from the sealing resin 40.

As shown in FIGS. 3 and 4, the first lead 10B includes a main portion 11, four side portions 12, and a plurality of protruding portions 13. The main portion 11 extends in the first direction x. Two of the four side portions 12 are connected to an end of the main portion 11 at the x1 side in the first direction x. The other two of the four side portions 12 are connected to an end of the main portion 11 at the x2 side in the first direction x. Each of the four side portions 12 includes a first end surface 121. As shown in FIG. 12, the first end surface 121 is connected to both the first main surface 101 and the first back surface 102 and faces the first direction x. The first end surface 121 is exposed from the sealing resin 40. The plurality of protruding portions 13 protrude from the y2 side of the main portion 11 in the second direction y. The sealing resin 40 is filled between two adjacent protruding portions 13. Each of the plurality of protruding portions 13 includes a sub end surface 131. As shown in FIG. 9, the sub end surface 131 is connected to both the first main surface 101 and the first back surface 102 and faces the y2 side in the second direction y. The sub end surface 131 is exposed from the sealing resin 40. As shown in FIG. 7, a plurality of sub end surfaces 131 are arranged at predetermined intervals along the first direction x. The first leads 10A, 10B, and 10C are not limited to shapes including the main portion 11 and the side portions 12.

In each of the first leads 10A, 10B, and 10C, the first back surface 102, the pair of first end surfaces 121, and the plurality of sub end surfaces 131 exposed from the sealing resin 40 may be subjected to, for example, Sn plating. Meanwhile, a plurality of metal platings, for example, Ni, Pd, and Au laminated in this order, may be used instead of the Sn plating.

As shown in FIG. 3, the plurality of second leads 21 are located on the y1 side in the second direction y relative to the first lead 10A. One of the plurality of second leads 21 is a ground terminal of the control circuit 322 of the semiconductor element 3, which is described later. Each of the remaining plurality of second leads 21 receives power (voltage) for driving the control circuit 322 or an electrical signal to be transmitted to the control circuit 322. As shown in FIGS. 3 and 4, each of the plurality of second leads 21 includes a second main surface 211, a second back surface 212, and a second end surface 213. Shapes of the second leads 21 are not limited in any way.

The second main surface 211 faces the same side as the first main surfaces 101 of the first leads 10A, 10B, and 10C in the thickness direction z and opposes the semiconductor element 3. The second main surface 211 is covered with the sealing resin 40. The semiconductor element 3 is supported by the second main surface 211. The second back surface 212 faces an opposite side to the second main surface 211. The second back surface 212 is exposed from the sealing resin 40. The second end surface 213 is connected to both the second main surface 211 and the second back surface 212 and faces the y1 side in the second direction y. The second end surface 213 is exposed from the sealing resin 40. As shown in FIG. 8, a plurality of second end surfaces 213 are arranged at predetermined intervals along the first direction x. Two second leads 21 disposed at both ends in the first direction x further include fourth end surfaces 214. The fourth end surfaces 214 face in the first direction x and are exposed from the sealing resin 40. In the illustrated example, as shown in FIGS. 3 and 4, in each of the plurality of second leads 21, an area of the second main surface 211 is larger than an area of the second back surface 212. A portion of each second lead 21 where the second main surface 211 does not overlap the second back surface 212 when viewed in the thickness direction z is formed, for example, by half-etching from a second back surface 212 side. This portion prevents each second lead 21 from falling off from the resin back surface 42 of the sealing resin 40 by virtue of an anchoring effect.

The second back surfaces 212, the second end surfaces 213, and the fourth end surfaces 214 of the plurality of second leads 21 exposed from the sealing resin 40 may be subjected to, for example, Sn plating. Meanwhile, a plurality of metal platings, for example, Ni, Pd, and Au laminated in this order, may be used instead of the Sn plating.

As shown in FIG. 3, the pair of third leads 22 are located between the first lead 10A and the plurality of second leads 21 in the second direction y. The pair of third leads 22 are spaced apart from each other in the first direction x. Each of the pair of third leads 22 receives an electrical signal, etc., to be transmitted to the control circuit 322 configured in the semiconductor element 3. As shown in FIGS. 3 and 4, each of the pair of third leads 22 includes a third main surface 221, a third back surface 222, and a third end surface 223. Meanwhile, a shape of the third lead 22 is not limited in any way.

The third main surface 221 faces the same side as the first main surfaces 101 of the first leads 10A, 10B, and 10C in the thickness direction z and opposes the semiconductor element 3. The third main surface 221 is covered with the sealing resin 40. The semiconductor element 3 is supported by the third main surface 221. The third back surface 222 faces an opposite side to the third main surface 221. The third back surface 222 is exposed from the sealing resin 40. The third end surface 223 is connected to both the third main surface 221 and the third back surface 222 and faces the first direction x. The third end surface 223 is exposed from the sealing resin 40. The third end surface 223, along with the first end surfaces 121 of the first leads 10A, 10B, and 10C, is arranged along the second direction y. In the illustrated example, in each of the pair of third leads 22, an area of the third main surface 221 is larger than an area of the third back surface 222. A portion of each third lead 22 where the third main surface 221 does not overlap the third back surface 222 when viewed in the thickness direction z is formed, for example, by half-etching from a third back surface 222 side. This portion prevents each third lead 22 from falling off from the resin back surface 42 of the sealing resin 40 by virtue of an anchoring effect.

The third back surface 222 and the third end surface 223 of the pair of third leads 22 exposed from the sealing resin 40 may be subjected to, for example, Sn plating. A plurality of metal platings, for example, Ni, Pd, and Au laminated in this order, may be used instead of the Sn plating. The number, shape, and arrangement of the first leads 10A, 10B, and 10C, the second leads 21, and the third leads 22 are not limited.

As shown in FIG. 2, the semiconductor element 3 is disposed at a center of the semiconductor device A10 when viewed in the thickness direction z. As shown in FIGS. 9 to 17, the semiconductor element 3 is located on the z1 side in the thickness direction z relative to the conductor 1 (the first leads 10A, 10B, and 10C, the plurality of second leads 21, and the pair of third leads 22). The semiconductor element 3 is supported by the first leads 10A, 10B, and 10C, the plurality of second leads 21, and the pair of third leads 22. The semiconductor element 3 is covered with the sealing resin 40. The semiconductor element 3 includes an element body 30, a passivation film 33, a plurality of conductive pads 34, an insulating layer 35, a plurality of first conductive columns 36A, and a plurality of second conductive columns 36B. The semiconductor element 3 is a flip-chip type LSI in which a circuit is configured.

The element body 30 is rectangular as shown in FIG. 2 when viewed in the thickness direction z and is plate-shaped as shown in FIGS. 9 to 13. The element body 30 forms a main part of the semiconductor element 3. As shown in FIGS. 9 to 13, the element body 30 includes a semiconductor substrate 31 and a semiconductor layer 32.

As shown in FIGS. 15 to 17, the semiconductor substrate 31 is provided with the semiconductor layer 32, the passivation film 33, the plurality of conductive pads 34, the insulating layer 35, the plurality of first conductive columns 36A, and the plurality of second conductive columns 36B, on its z2 side in the thickness direction z. A constituent material of the semiconductor substrate 31 is, for example, silicon (Si) or silicon carbide (SiC).

As shown in FIGS. 9 to 13, the semiconductor layer 32 is laminated on the z2 side of the semiconductor substrate 31 in the thickness direction z. The semiconductor layer 32 includes a plurality of types of p-type and n-type semiconductors based on a difference in amounts of doped elements. The semiconductor layer 32 is configured with a switching circuit 321 and a control circuit 322 that is electrically connected to the switching circuit 321. The switching circuit 321 is a metal-oxide-semiconductor field-effect transistor (MOSFET), an insulated gate bipolar transistor (IGBT), or the like. In the example of the semiconductor device A10, the switching circuit 321 is divided into two regions: a high-voltage region (upper arm circuit) and a low-voltage region (lower arm circuit). Each region is constituted by one n-channel MOSFET. The control circuit 322 is configured with a gate driver for driving the switching circuit 321, a bootstrap circuit corresponding to the high-voltage region of the switching circuit 321, or the like, and performs control for driving the switching circuit 321 normally. A wiring layer (not shown) is further configured in the semiconductor layer 32. The wiring layer provides mutual conductivity between the switching circuit 321 and the control circuit 322. The switching circuit 321 and the control circuit 322 are examples of a "circuit" in the present disclosure.

As shown in FIGS. 15 to 17, the passivation film 33 covers a surface of the semiconductor layer 32 on the z2 side in the thickness direction z. The passivation film 33 has electrical insulation properties. The passivation film 33 is composed, for example, of a silicon oxide (SiO₂) film laminated in contact with the semiconductor layer 32 and a silicon nitride (Si₃N₄) film laminated on the silicon oxide film.

The plurality of conductive pads 34 are formed on a surface of the passivation film 33 on the z2 side in the thickness direction z. Each of the conductive pads 34 (excluding some conductive pads 34 to be described below) is connected to a wiring layer formed on the semiconductor layer 32 via an opening (not shown) provided in the passivation film 33. As a result, the conductive pads 34 (excluding some conductive pads 34) are electrically connected to either the switching circuit 321 or the control circuit 322 of the semiconductor layer 32. In this embodiment, the conductive pads 34 are composed of a plurality of metal layers laminated from the passivation film 33 toward the z2 side in the thickness direction z, and include a first layer 34a, a second layer 34b, and a third layer 34c. The first layer 34a contacts the passivation film 33 and is made of Cu. The second layer 34b contacts the first layer 34a and is made of Ni. The third layer 34c contacts the second layer 34b and is made of Pd. A configuration of the conductive pad 34 is not limited.

As shown in FIGS. 15 to 17, the insulating layer 35 is formed on the z2 side of the passivation film 33 in the thickness direction z and covers a portion of the passivation film 33 and the conductive pad 34. The insulating layer 35 has electrical insulation properties. In this embodiment, a constituent material of the insulating layer 35 is phenolic resin. The constituent material of the insulating layer 35 is not limited, and may be made of other insulating materials such as polyimide resin. The insulating layer 35 includes a plurality of openings 35a. From each of the plurality of openings 35a, one of the conductive pads 34 is exposed. The insulating layer 35 is formed, for example, by applying photolithography to a photosensitive resin material applied by a spin coater.

As shown in FIGS. 9 to 14, the plurality of first conductive columns 36A and the plurality of second conductive columns 36B are interposed in the thickness direction z between the element body 30 and the first main surface 101, second main surface 211, and third main surface 221 of the conductor 1 (the first leads 10A, 10B, and 10C, the plurality of second leads 21, and the pair of third leads 22). The plurality of first conductive columns 36A and the plurality of second conductive columns 36B protrude from a side of the element body 30 opposing the first main surface 101, the second main surface 211, and the third main surface 221 of the conductor 1 toward the first main surface 101, the second main surface 211, and the third main surface 221 of the conductor 1. Further, as shown in FIGS. 15 to 17, through the opening 35a in the insulating layer 35, each of the plurality of first conductive columns 36A and the plurality of second conductive columns 36B contacts one of the conductive pads 34. Each of the first conductive columns 36A and each of the second conductive columns 36B contacts the conductive pad 34 at their central portions and overlap the insulating layer 35 at their peripheral portions when viewed in the thickness direction z. Each of the first conductive columns 36A and each of the second conductive columns 36B has electrical conductivity.

As shown in FIGS. 15 to 17, each of the plurality of first conductive columns 36A and the plurality of second conductive columns 36B includes a seed layer 361, a first plating layer 362, and a second plating layer 363. The seed layer 361 is in contact with the conductive pad 34 and the insulating layer 35 and contains Cu. The seed layer 361 is formed, for example, by electroless plating. A constituent material and formation method of the seed layer 361 are not limited. For example, the seed layer 361 may be formed by sputtering. The first plating layer 362 is laminated on the seed layer 361 and is made of, for example, Cu or a Cu alloy. The first plating layer 362 is formed by electroplating. A constituent material of the first plating layer 362 is not limited. The second plating layer 363 is laminated on the first plating layer 362. The second plating layer 363 is interposed between the first plating layer 362 and a bonding material 5 and functions to suppress a chemical reaction between the first plating layer 362 and the bonding material 5. A constituent material of the second plating layer 363 is not particularly limited, and a metal capable of suppressing the chemical reaction may be appropriately selected, such as Ni or Fe. In this embodiment, since the first plating layer 362 contains Cu and the bonding material 5 contains Sn, the second plating layer 363 is made of, for example, Ni. In this embodiment, the second plating layer 363 is formed by electroplating. A constituent material and formation method of the second plating layer 363 are not limited. Further, the second plating layer 363 may not be required. Each first conductive column 36A includes a first bonding surface 365A. Each second conductive column 36B includes a second bonding surface 365B. The first bonding surface 365A and the second bonding surface 365B are surfaces facing an opposite side to the conductive pad 34 (surfaces facing the first main surface 101, the second main surface 211, and the third main surface 221), and are bonded, via the bonding material 5, to a metal layer 6 formed on the first main surface 101, the second main surface 211, or the third main surface 221.

The plurality of first conductive columns 36A are electrically connected to the switching circuit 321 of the semiconductor layer 32. Further, the plurality of first conductive columns 36A are conductively bonded to the first main surfaces 101 of the first leads 10A, 10B, and 10C. As a result, the first leads 10A, 10B, and 10C are electrically connected to the switching circuit 321. A shape of the first conductive column 36A when viewed in the thickness direction z (in a plan view) is circular, and the first bonding surface 365A of the first conductive column 36A also has a circular shape. A diameter D1 (see FIG. 15 ) of the first bonding surface 365A is not particularly limited, but as an example, it is 150 μm.

The plurality of second conductive columns 36B (excluding some second conductive columns 36B to be described below) are electrically connected to the control circuit 322 of the semiconductor layer 32. Further, as shown in FIG. 3, two second conductive columns 36B are conductively bonded to the third main surfaces 221 of the pair of third leads 22, respectively. Other seven second conductive columns 36B are conductively bonded to the second main surfaces 211 of the plurality of second leads 21, respectively. As a result, the pair of third leads 22 and the plurality of second leads 21 are electrically connected to the control circuit 322. On the other hand, the remaining two second conductive columns 36B are not electrically connected to either the switching circuit 321 or the control circuit 322 and are insulated from the switching circuit 321 and the control circuit 322 (circuit). In this embodiment, the remaining two second conductive columns 36B are each conductively bonded to the first main surface 101 of the first lead 10B. A shape of the second conductive columns 36B when viewed in the thickness direction z (in a plan view) is circular, and the second bonding surface 365B of the second conductive column 36B also has a circular shape. A diameter D2 of the second bonding surface 365B (see FIGS. 16 and 17) is not particularly limited, but as an example, it is 100 μm.

A second area S2 of the second bonding surface 365B is different from a first area S1 of the first bonding surface 365A of the first conductive column 36A. In this embodiment, the diameter D2 of the second bonding surface 365B is smaller than the diameter D1 of the first bonding surface 365A, and the second area S2 of the second bonding surface 365B is smaller than the first area S1 of the first bonding surface 365A. The first area S1 of the first bonding surface 365A is, for example, 1.2 times or more the second area S2 of the second bonding surface 365B. The first area S1 of the first bonding surface 365A is desirably 1.2 times or more and 5.0 times or less the second area S2 of the second bonding surface 365B. Since a larger current flows through the first conductive column 36A than through the second conductive column 36B, the first area S1 is made larger than the second area S2.

As described above, the diameter D1 of the first conductive column 36A (the first area S1 of the first bonding surface 365A) is larger than the diameter D2 of the second conductive column 36B (the second area S2 of the second bonding surface 365B). In forming the first conductive column 36A and the second conductive column 36B, plating processes for forming the first conductive column 36A and the second conductive column 36B are performed using the same process. A thickness of the plating layer formed by such a plating process using the same process decreases as the diameter (area) increases, and increases as the diameter (area) decreases. In this embodiment, since the diameter D2 (the second area S2) is smaller than the diameter D1 (the first area S1), a thickness t2 (dimension in the thickness direction z) of the second conductive column 36B is larger than a thickness t1 (dimension in the thickness direction z) of the first conductive column 36A.

One or more metal layers 6 are formed on each first main surface 101 of the first leads 10A, 10B, and 10C, each second main surface 211 of the plurality of second leads 21, and each third main surface 221 of the pair of third leads 22. Each metal layer 6 is disposed to align with positions of the first conductive columns 36A or the second conductive columns 36B of the semiconductor element 3. As shown in FIGS. 15 to 17, each metal layer 6 is interposed between the first conductive columns 36A or the second conductive columns 36B and one of the first main surfaces 101 of the first leads 10A, 10B, and 10C, the second main surfaces 211 of the plurality of second leads 21, and the third main surfaces 221 of the pair of third leads 22, and thus the first conductive columns 36A and the second conductive columns 36B are bonded to the metal layer 6 by the bonding material 5. The metal layer 6 suppresses a chemical reaction between the bonding material 5 and the first leads 10A, 10B, and 10C, the second lead 21, and the third lead 22, and also limits a range over which the bonding material 5 spreads when the semiconductor element 3 is bonded.

In this embodiment, the metal layer 6 is configured, for example, by laminating a plurality of metal layers. The metal layer 6 includes, for example, a first layer, a second layer, and a third layer (both not shown). The first layer is laminated in contact with one of the first main surfaces 101 of the first leads 10A, 10B, and 10C, the second main surfaces 211 of the plurality of second leads 21, or the third main surfaces 221 of the pair of third leads 22. In this embodiment, since the first leads 10A, 10B, and 10C, the plurality of second leads 21, and the third leads 22 contain Cu and the bonding material 5 contains Sn, the first layer is made of, for example, Ni. The second layer is laminated in contact with the first layer. A constituent material of the second layer is not particularly limited and includes, for example, Pd. The third layer is laminated in contact with the second layer. The third layer is made of a constituent material that exhibits relatively good wettability with the bonding material 5 (solder). The constituent material of the third layer is not particularly limited and includes, for example, Au. A method for forming the metal layer 6 is not limited. Further, the metal layer 6 is not limited to the configuration including the above-described first, second, and third layers.

A plurality of metal layers 6 include a plurality of metal layers 6A and a plurality of metal layers 6B.

As shown in FIG. 3, each metal layer 6A is disposed on the first main surfaces 101 of each of the first leads 10A, 10B, and 10C. The first conductive column 36A of the semiconductor element 3 is bonded to each metal layer 6A. A shape of each metal layer 6A when viewed in the thickness direction z is circular, matching the shape of the first bonding surface 365A of the first conductive column 36A. As shown in FIG. 15, a diameter D3 of the metal layer 6A is larger than the diameter D1 of the first bonding surface 365A. Further, as shown in FIG. 3, when viewed in the thickness direction z, the first conductive column 36A (the first bonding surface 365A) is enclosed within the metal layer 6A.

As shown in FIG. 3, each metal layer 6B is disposed on each second main surface 211, each third main surface 221, and the first main surface 101 of the first lead 10B. The second conductive column 36B of the semiconductor element 3 is bonded to each metal layer 6B. A shape of each metal layer 6B when viewed in the thickness direction z is circular, matching the shape of the second bonding surface 365B of the second conductive column 36B. As shown in FIGS. 16 and 17, a diameter D4 of the metal layer 6B is larger than the diameter D2 of the second bonding surface 365B. Further, as shown in FIG. 3, when viewed in the thickness direction z, the second conductive column 36B (the second bonding surface 365B) is enclosed within the metal layer 6B.

The bonding material 5 has electrical conductivity and is interposed between the metal layer 6 and the first conductive column 36A or the second conductive column 36B, thereby providing electrical connection between them. In this embodiment, the bonding material 5 is made of, for example, solder containing Sn (e.g., SnAg). A constituent material of the bonding material 5 is not limited.

A plurality of bonding materials 5 include a plurality of first bonding materials 5A and a plurality of second bonding materials 5B. As shown in FIG. 15, the first bonding material 5A is interposed between the first bonding surface 365A of the first conductive column 36A and the metal layer 6A, thereby bonding them together. The first bonding material 5A has a truncated cone shape with its upper surface (a surface facing the z1 side in the thickness direction z) in contact with the first bonding surface 365A and its lower surface (a surface facing the z2 side in the thickness direction z) in contact with the metal layer 6A. As shown in FIGS. 16 and 17, the second bonding material 5B is interposed between the second bonding surface 365B of the second conductive column 36B and the metal layer 6B, thereby bonding them together. The second bonding material 5B has a truncated cone shape with its upper surface (a surface facing the z1 side in the thickness direction z) in contact with the second bonding surface 365B and its lower surface (a surface facing the z2 side in the thickness direction z) in contact with the metal layer 6B.

In this embodiment, as shown in FIG. 3, among the plurality of first conductive columns 36A and the plurality of second conductive columns 36B, four second conductive columns 36B are disposed at positions closest to four corners (four corners 301) of the element body 30, respectively. These four second conductive columns 36B may be referred to as "corner-proximal columns 36B1" as appropriate to distinguish them from the other second conductive columns 36B.

In this embodiment, the plurality of first conductive columns 36A are bonded to the first main surfaces 101 of the first leads 10A, 10B, and 10C and are disposed closer to the y2 side in the second direction y when viewed in the thickness direction z. Most of the plurality of second conductive columns 36B are bonded to the second main surfaces 211 of the plurality of second leads 21 and the third main surfaces 221 of the pair of third leads 22 and are disposed closer to the y1 side in the second direction y when viewed in the thickness direction z. The remaining two second conductive columns 36B are bonded to the first main surface 101 of the first lead 10B and are disposed closer to the y2 side in the second direction y than the plurality of first conductive columns 36A when viewed in the thickness direction z. Of the four second conductive columns 36B (corner-proximal columns 36B1), two corner-proximal columns 36B1 are located on the y1 side in the second direction y and are closest to the two corners 301 of the element body 30 on the y1 side in the second direction y. The two corner-proximal columns 36B1 are bonded to the second main surface 211 of the second lead 21 and are electrically connected to the control circuit 322. Of the four second conductive columns 36B (corner-proximal columns 36B1), the remaining two corner-proximal columns 36B1 are located on the y2 side in the second direction y and are closest to the two corners 301 of the element body 30 on the y1 side in the second direction y. These remaining two corner-proximal columns 36B1 are bonded to the first main surface 101 of the first lead 10B and are insulated from the switching circuit 321 and the control circuit 322 (circuit).

The sealing resin 40 covers the entire semiconductor element 3 and a portion of each of the first leads 10A, 10B, and 10C, the plurality of second leads 21, and the pair of third leads 22. The sealing resin 40 is made of a material containing, for example, black epoxy resin. The material of the sealing resin 40 is not limited. The sealing resin 40 is rectangular when viewed in the thickness direction z, and includes a resin main surface 41, a resin back surface 42, a pair of first resin side surfaces 431, and a pair of second resin side surfaces 432, as shown in FIGS. 5 to 8.

As shown in FIGS. 9 to 14, the resin main surface 41 faces the same side as the first main surfaces 101 of the first leads 10A, 10B, and 10C in the thickness direction z. As shown in FIGS. 5 to 8, the resin back surface 42 faces an opposite side to the resin main surface 41. As shown in FIG. 4, the first back surfaces 102 of the first leads 10A, 10B, and 10C, the second back surfaces 212 of the plurality of second leads 21, and the third back surfaces 222 of the pair of third leads 22 are exposed from the resin back surface 42.

As shown in FIGS. 7 and 8, the pair of first resin side surfaces 431 are connected to both the resin main surface 41 and the resin back surface 42 and face the first direction x. The pair of first resin side surfaces 431 are spaced apart from each other in the first direction x. As shown in FIGS. 5, 6, and 11 to 13, the first end surfaces 121 of the first leads 10A, 10B, and 10C, the fourth end surface 214 of the second lead 21, and the third end surface 223 of the third lead 22 are exposed from each of the pair of first resin side surfaces 431 so as to be flush with the first resin side surfaces 431.

As shown in FIGS. 5 and 6, the pair of second resin side surfaces 432 are connected to all of the resin main surface 41, the resin back surface 42, and the pair of first resin side surfaces 431 and face in the second direction y. The pair of second resin side surfaces 432 are spaced apart from each other in the second direction y. As shown in FIGS. 9, 10, and 14, the second end surfaces 213 of the plurality of second leads 21 are exposed from the second resin side surface 432 located on the y1 side in the second direction y so as to be flush with the second resin side surface 432. The plurality of sub end surfaces 131 of the first lead 10B are exposed from the second resin side surface 432 located on the y2 side in the second direction y so as to be flush with the second resin side surface 432.

Next, operations and effects of the semiconductor device A10 are described.

In the semiconductor device A10, the semiconductor element 3 includes the element body 30 that is rectangular when viewed in the thickness direction z, the plurality of first conductive columns 36A, and the plurality of second conductive columns 36B. The plurality of first conductive columns 36A protrude from the element body 30 toward the z2 side in the thickness direction z and are bonded to the first main surfaces 101 of the conductor 1 (the first leads 10A, 10B, and 10C). The plurality of second conductive columns 36B protrude from the element body 30 toward the z2 side in the thickness direction z and are bonded to the first main surface 101, the second main surface 211, and the third main surface 221 of the conductor 1 (the first lead 10B, the plurality of second leads 21, and the pair of third leads 22). Of the plurality of first conductive columns 36A and the plurality of second conductive columns 36B, the four second conductive columns 36B (corner-proximal columns 36B1) are closest to the four corners (the four corners 301) of the element body 30, respectively.

In the semiconductor device A10, the first area S1 of the first bonding surface 365A (the first conductive column 36A) is different from the second area S2 of the second bonding surface 365B (the second conductive column 36B), and the thickness t1 of the first conductive column 36A is different from the thickness t2 of the second conductive column 36B. In this embodiment, among the plurality of first conductive columns 36A and the plurality of second conductive columns 36B, the four second conductive columns 36B (corner-proximal columns 36B1) with the same dimension (thickness t2) in the thickness direction z are disposed at positions closest to each of the four corners 301 of the element body 30. According to this configuration, bonding conditions with the bonding material 5 and the like are the same for the second conductive columns 36B (corner-proximal columns 36B1), which are located at the four corners, among the plurality of first conductive columns 36A and the plurality of second conductive columns 36B. Therefore, even if arrangements of the plurality of first conductive columns 36A and the plurality of second conductive columns 36B are uneven when viewed in the thickness direction z, parallelism between the element body 30 (the semiconductor element 3) and the first main surfaces 101, the second main surfaces 211, and the third main surfaces 221 of the conductor 1 is maintained at a high level. Therefore, it is possible to prevent the semiconductor element 3 flip-chip mounted on the conductor 1 (the first leads 10A, 10B, and 10C, the plurality of second leads 21, and the pair of third leads 22) from tilting, thereby improving bonding reliability of the semiconductor element 3 mounted by flip-chip mounting.

In this embodiment, the second area S2 of the second bonding surface 365B (the second conductive column 36B) is smaller than the first area S1 of the first bonding surface 365A (the first conductive column 36A). The thickness t2 (the dimension in the thickness direction z) of the second conductive column 36B is larger than the thickness t1 (the dimension in the thickness direction z) of the first conductive column 36A. In this embodiment, since the thickness t2 of the four second conductive columns 36B (corner-proximal columns 36B1) closest to each of the four corners (the four corners 301) of the element body 30 is increased, a support state of the semiconductor element 3 mounted on the conductor 1 (the first leads 10A, 10B, and 10C, the plurality of second leads 21, and the pair of third leads 22) by flip-chip mounting becomes more stable. This is more suitable for improving the bonding reliability of the semiconductor element 3 mounted by flip-chip mounting.

In this embodiment, the four corner-proximal columns 36B1 include those insulated from the switching circuit 321 and the control circuit 322 (circuit). According to this configuration, by providing the corner-proximal column 36B1 that does not contribute electrically and by devising the arrangement of the corner-proximal column 36B1, it is possible to improve the bonding reliability of the semiconductor element 3 mounted by flip-chip mounting as described above.

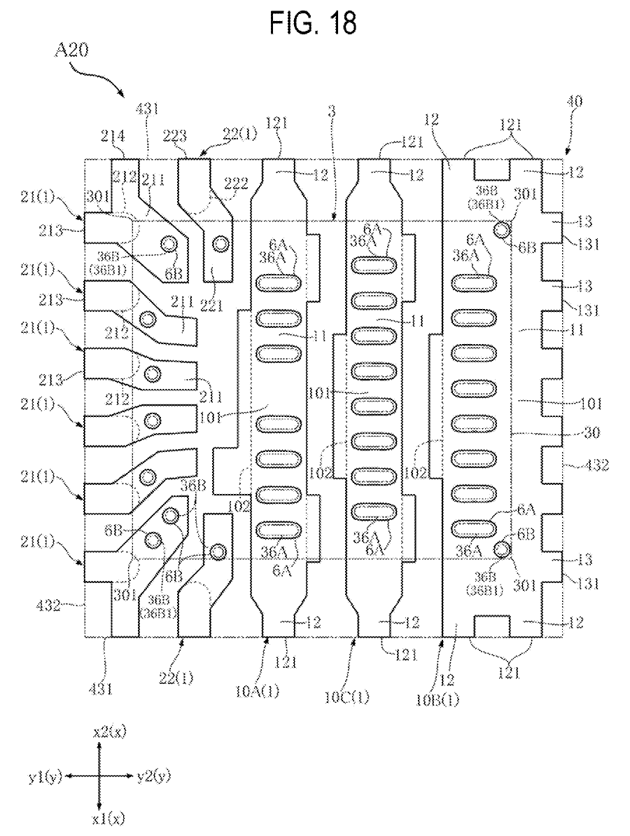

FIGS. 18 to 21 show other embodiments of the present disclosure. In these figures, the same or similar elements as those in the above-described embodiment are denoted by the same reference numerals as in the above-described embodiment, and redundant explanations are omitted.

### Second Embodiment

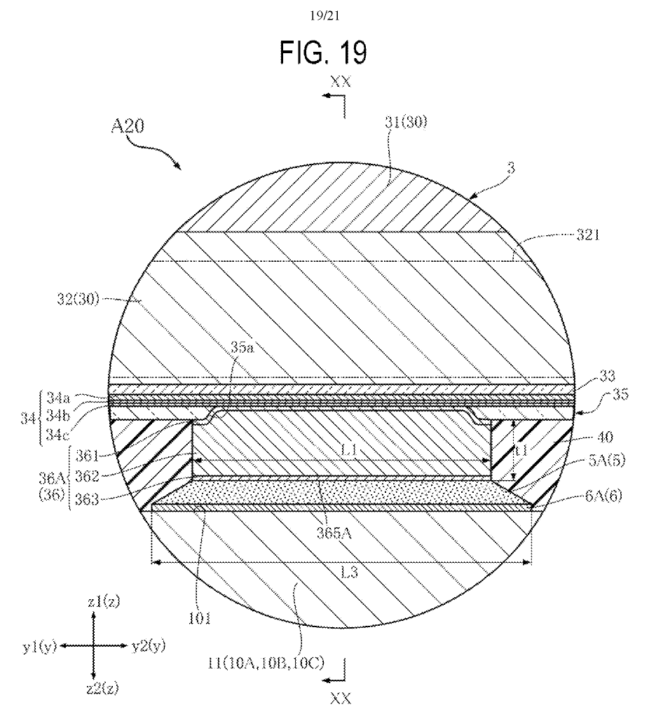

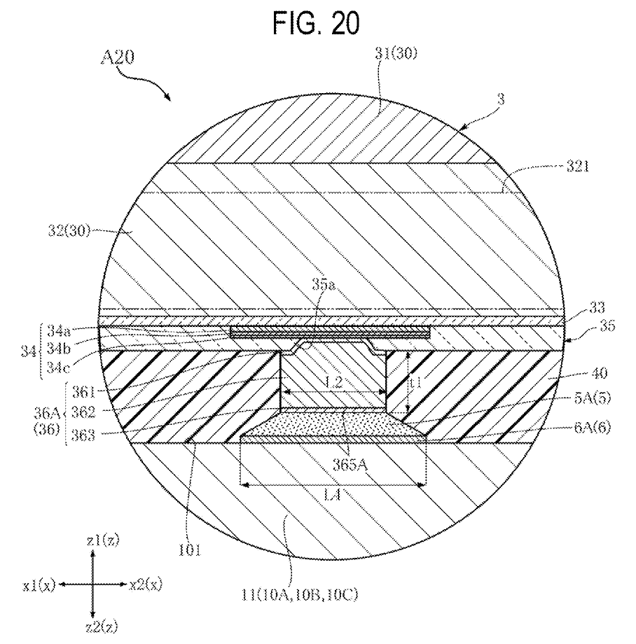

FIGS. 18 to 20 are diagrams illustrating a semiconductor device A20 according to a second embodiment of the present disclosure. FIG. 18 is a plan view showing the semiconductor device A20 and corresponds to FIG. 3. In FIG. 18, for ease of understanding, the sealing resin 40 and the semiconductor element 3 are shown through and outlines of the sealing resin 40 and the semiconductor element 3 are indicated by imaginary lines (two-dot chain lines). FIG. 19 is a partially enlarged cross-sectional view of the semiconductor device A20 and corresponds to FIG. 15. FIG. 20 is a partially enlarged cross-sectional view taken along line XX-XX in FIG. 19. The semiconductor device A20 of this embodiment is different from the first embodiment in the shapes of the first conductive column 36A and the metal layer 6A. Configurations and operations of other components of this embodiment are the same as those of the first embodiment.

In this embodiment, the shape of each first conductive column 36A when viewed in the thickness direction z (in a plan view) is the same elliptical shape. Accordingly, the first bonding surface 365A of each first conductive column 36A also has the same elliptical shape. As shown in FIGS. 18 and 19, a longitudinal direction (direction of a major axis) of the first bonding surface 365A of the first conductive column 36A is perpendicular to an extension direction of the first leads 10A, 10C, and 10B. A relationship between the longitudinal direction of the first bonding surface 365A and the extension direction of the first leads 10A, 10C, and 10B is not limited to this perpendicular relationship. Dimensions of the first bonding surface 365A are not particularly limited. For example, a major axis L1 (dimension in the second direction y, see FIG. 19) is, for example, 300 μm, and a minor axis L2 (dimension in the first direction x, see FIG. 20) is, for example, 100 μm. The first area S1 of the first bonding surface 365A is larger than the second area S2 of the second bonding surface 365B. The first area S1 of the first bonding surface 365A is, for example, 1.2 times or more the second area S2 of the second bonding surface 365B. The first area S1 is desirably 1.2 times or more and 5.0 times or less the second area S2.

Further, in this embodiment, the shape of each metal layer 6A when viewed in the thickness direction z is also elliptical to match the shape of each first bonding surface 365A. As shown in FIG. 19, a major axis L3 (dimension in the second direction y) of the metal layer 6A is longer than the major axis L1 of the first bonding surface 365A. As shown in FIG. 20, a minor axis L4 (dimension in the first direction x) of the metal layer 6A is longer than the minor axis L2 of the first bonding surface 365A. Furthermore, as shown in FIG. 18, when viewed in the thickness direction z, the first conductive column 36A (the first bonding surface 365A) is enclosed within the metal layer 6A.

In the semiconductor device A20, among the plurality of first conductive columns 36A and the plurality of second conductive columns 36B, four second conductive columns 36B (corner-proximal columns 36B1) with the same dimension in the thickness direction z (thickness t2) are disposed at positions closest to each of the four corners 301 of the element body 30. According to this configuration, bonding conditions with the bonding material 5 and the like are the same for the second conductive columns 36B (corner-proximal columns 36B1), which are located at the four corners, among the plurality of first conductive columns 36A and the plurality of second conductive columns 36B. Therefore, even if arrangements of the plurality of first conductive columns 36A and the plurality of second conductive columns 36B are uneven when viewed in the thickness direction z, parallelism between the element body 30 (the semiconductor element 3) and the first main surface 101, the second main surface 211, and the third main surface 221 of the conductor 1 is maintained at a high level. Therefore, it is possible to prevent the semiconductor element 3 flip-chip mounted on the conductor 1 (the first leads 10A, 10B, and 10C, the plurality of second leads 21, and the pair of third leads 22) from tilting, thereby improving bonding reliability of the semiconductor element 3 mounted by flip-chip mounting. In addition, the semiconductor device A20 exhibits the same operation and effects as the semiconductor device A10 of the above-described embodiment.

### Third Embodiment

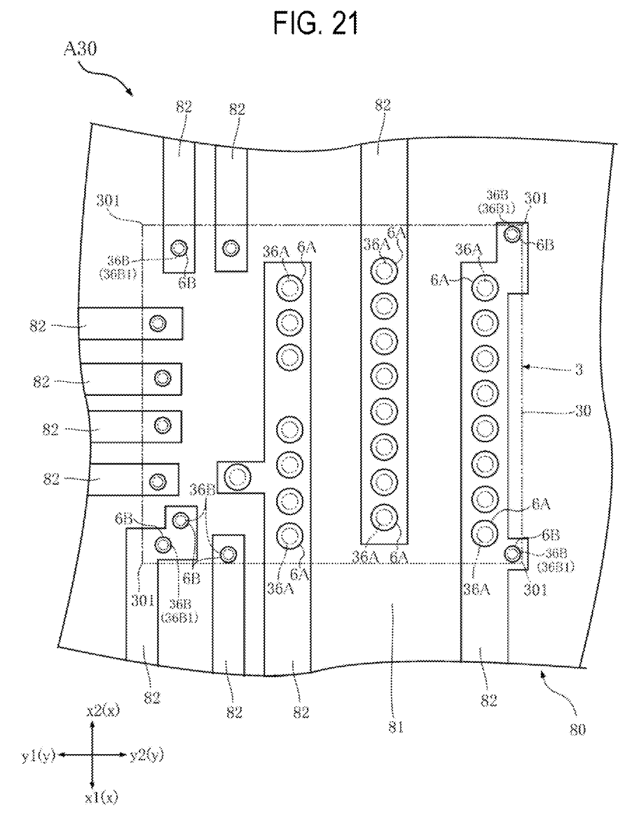

FIG. 21 is a diagram illustrating a semiconductor device A30 according to a third embodiment of the present disclosure. FIG. 21 is a partial plan view showing the semiconductor device A30 and corresponds to FIG. 3. In FIG. 21, for ease of understanding, the sealing resin 40 and the semiconductor element 3 are shown through and the semiconductor element 3 is indicated by an imaginary line (two-dot chain line). The semiconductor device A30 of this embodiment is different from the first embodiment in that the semiconductor element 3 is mounted on a wiring substrate rather than on leads. Configuration and operations of other components of this embodiment are the same as those of the first embodiment. The components of the first and second embodiments may be combined in any desired manner.

In the above-described first and second embodiments, a case has been described where the semiconductor element 3 is mounted on the first leads 10A, 10B, and 10C, the plurality of second leads 21, and the pair of third leads 22, and the first conductive columns 36A and the second conductive columns 36B are bonded to these leads. However, the semiconductor element 3 may be bonded to a conductor other than the leads. In the third embodiment, the semiconductor device A30 is described in which the semiconductor element 3 is mounted on a wiring substrate, and the first conductive columns 36A and the second conductive columns 36B are bonded to wirings of the wiring substrate.

The semiconductor device A30 does not include the first leads 10A, 10B, and 10C, the second leads 21, and the third leads 22, but instead includes a wiring substrate 80. The wiring substrate 80 includes an insulating substrate 81 and a plurality of wirings 82. The insulating substrate 81 is a rectangular plate made of an electrically insulating material such as glass epoxy resin or ceramic. A material and a shape of the insulating substrate 81 are not limited. The wirings 82 are made of, for example, Cu and are formed on the insulating substrate 81. A material and a shape of the wirings 82 are not limited.

The semiconductor element 3 is flip-chip mounted on the wiring substrate 80. Each first conductive column 36A and each second conductive column 36B is bonded to an upper surface (main surface) of one of the plurality of wirings 82 of the wiring substrate 80. One or more metal layers 6 are formed on each wiring 82. Each metal layer 6 is disposed to match a position of the first conductive column 36A or the second conductive column 36B of the semiconductor element 3. Each metal layer 6 is interposed between one of the wirings 82 and the first conductive column 36A or the second conductive column 36B, and thus the first conductive column 36A or the second conductive column 36B is bonded to the metal layer 6 by a bonding material 5. The metal layer 6 suppresses a chemical reaction between the wiring 82 and the bonding material 5, and also limits a range over which the bonding material 5 spreads when the semiconductor element 3 is bonded. As in the first embodiment, the plurality of metal layers 6 include a plurality of metal layers 6A and a plurality of metal layers 6B. The first conductive column 36A of the semiconductor element 3 is bonded to each metal layer 6A. The second conductive column 36B of the semiconductor element 3 is bonded to each metal layer 6B. The entire semiconductor element 3 and at least a portion of the wiring substrate 80 are covered with the sealing resin 40 (not shown in FIG. 21). Other electronic components may be mounted on the wiring substrate 80, or leads may be bonded to mount the semiconductor device A30 on the wiring substrate.

In the semiconductor device A30, among the plurality of first conductive columns 36A and the plurality of second conductive columns 36B, four second conductive columns 36B (corner-proximal columns 36B1) with the same dimension in the thickness direction z are disposed at positions closest to each of the four corners 301 of the element body 30. According to this configuration, bonding conditions with the bonding material 5 and the like are the same for the second conductive columns 36B (corner-proximal columns 36B1), which are located at the four corners, among the plurality of first conductive columns 36A and the plurality of second conductive columns 36B. Therefore, even if arrangements of the plurality of first conductive columns 36A and the plurality of second conductive columns 36B are uneven when viewed in the thickness direction z, parallelism between the wiring 82 (the wiring substrate 80) and the element body 30 (the semiconductor element 3) is maintained at a high level. Therefore, it is possible to prevent the semiconductor element 3 flip-chip mounted on the wiring substrate 80 from tilting, thereby improving bonding reliability of the semiconductor element 3 mounted by flip-chip mounting. In addition, the semiconductor device A30 exhibits the same operation and effects as the semiconductor device A10 of the above-described embodiment.

The semiconductor devices according to the present disclosure are not limited to the above-described embodiments. A specific configuration of each component of the semiconductor devices according to the present disclosure may be freely designed in various ways.

In the above-described embodiments, a case has been described where the semiconductor element 3 is an LSI, but the present disclosure is not limited thereto. The type of semiconductor element 3 is not limited. Further, in the above-described embodiments, some of the four second conductive columns 36B (corner-proximal columns 36B1) are insulated from the switching circuit 321 and the control circuit 322 (circuit) and bonded to the first main surface 101 of the first lead 10B, but the present disclosure is not limited thereto. For example, the corner-proximal columns 36B1 bonded to the first main surface 101 of the first lead 10B may be electrically connected to the switching circuit 321. In this case, the corner-proximal columns 36B1 (the second conductive columns 36B) bonded to the first main surface 101 serve as a current path between the first lead 10B and the switching circuit 321 (the semiconductor layer 32), similar to the first conductive column 36A bonded to the first lead 10B.

The present disclosure includes configurations related to the following supplementary notes.

### Supplementary Note 1

A semiconductor device including:

a conductor (1) including a main surface (101, 211, 221) facing one side (z1 side) in a thickness direction (z); and

a semiconductor element (3) located on the one side (z1 side) in the thickness direction (z) relative to the conductor (1) and supported by the main surface (101, 211, 221),

wherein the semiconductor element (3) includes:

an element body (30) that is rectangular when viewed in the thickness direction (z),

a plurality of first conductive columns (36A) each protruding from the element body (30) to the other side (z2 side) in the thickness direction (z) and bonded to the main surface (101); and

a plurality of second conductive columns (36B) each protruding from the element body (30) to the other side (z2 side) in the thickness direction (z) and bonded to the main surface (101, 211, 221),

wherein each of the plurality of first conductive columns (36A) includes a first bonding surface (365A) facing the main surface (101), each of the plurality of second conductive columns (36B) includes a second bonding surface (365B) facing the main surface (101, 211, 221), and a first area (S1) of the first bonding surface (365A) and a second area (S2) of the second bonding surface (365B) are different, and

wherein, among the plurality of first conductive columns (36A) and the plurality of second conductive columns (36B), four second conductive columns (36B1) are closest to four corners (301) of the element body (30).

### Supplementary Note 2

The semiconductor device of Supplementary Note 1, wherein the second area (S2) is smaller than the first area (S1).

### Supplementary Note 3

The semiconductor device of Supplementary Note 2, wherein the first area (S1) is 1.2 times or more the second area (S2).

### Supplementary Note 4

The semiconductor device of any one of Supplementary Notes 1 to 3, wherein the element body (30) includes a circuit (321, 322), and

wherein each of the plurality of first conductive columns (36A) is electrically connected to the circuit (321).

### Supplementary Note 5

The semiconductor device of Supplementary Note 4, wherein at least one of the four second conductive columns (36B1) is insulated from the circuit (321, 322).

### Supplementary Note 6

The semiconductor device of Supplementary Note 2 or 3, wherein a dimension (t2) of each of the plurality of second conductive columns (36B) in the thickness direction (z) is larger than a dimension (t1) of each of the plurality of first conductive columns (36A) in the thickness direction (z).

### Supplementary Note 7

The semiconductor device of any one of Supplementary Notes 1 to 6, wherein the first bonding surface (365A) is circular and the second bonding surface (365B) is circular.

### Supplementary Note 8

The semiconductor device of any one of Supplementary Notes 1 to 6, wherein the first bonding surface (365A) is elliptical and the second bonding surface (365B) is circular.

### Supplementary Note 9

The semiconductor device of any one of Supplementary Notes 1 to 8, further including:

a first bonding material (5A) interposed between the first bonding surface (365A) and the main surface (101); and

a second bonding material (5B) interposed between the second bonding surface (365B) and the main surface (101, 211, 221).

### Supplementary Note 10

The semiconductor device of Supplementary Note 9, wherein the first bonding material (5A) and the second bonding material (5B) include solder.

### Supplementary Note 11

The semiconductor device of any one of Supplementary Notes 1 to 10, wherein the conductor (1) contains Cu.

### Supplementary Note 12

The semiconductor device of any one of Supplementary Notes 1 to 11, wherein the plurality of first conductive columns (36A) and the plurality of second conductive columns (36B) contain Cu.

### Supplementary Note 13

The semiconductor device of any one of Supplementary Notes 1 to 12, wherein the conductor (1) is constituted by a lead.

### Supplementary Note 14

The semiconductor device of Supplementary Note 2 or 3, wherein the conductor (1) includes a first lead (10A, 10B, 10C), a second lead (21), and a third lead (22),

wherein each of the plurality of first conductive columns (36A) is bonded to the first lead (10A, 10B, 10C), and

wherein, among the plurality of second conductive columns (36B), at least one of the four second conductive columns (36B1) is bonded to the first lead (10B), and each of the other second conductive columns (36B) is bonded to the second lead (21) or the third lead (22).

### Supplementary Note 15

The semiconductor device of Supplementary Note 14, wherein the element body (30) includes a circuit (321, 322),

wherein each of the plurality of first conductive columns (36A) is electrically connected to the circuit (321), and

wherein, among the four second conductive columns (36B1), the second conductive column (36B1) bonded to the first lead (10B) is insulated from the circuit (321, 322).

### Supplementary Note 16

The semiconductor device of any one of Supplementary Notes 1 to 12, further including: an insulating substrate (81),

wherein the conductor is a wiring (82) formed on the insulating substrate (81).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a conductor including a main surface facing one side in a thickness direction; and
a semiconductor element located on the one side in the thickness direction relative to the conductor and supported by the main surface,
wherein the semiconductor element includes:
an element body that is rectangular when viewed in the thickness direction,
a plurality of first conductive columns each protruding from the element body to the other side in the thickness direction and bonded to the main surface; and
a plurality of second conductive columns each protruding from the element body to the other side in the thickness direction and bonded to the main surface,
wherein each of the plurality of first conductive columns includes a first bonding surface facing the main surface, each of the plurality of second conductive columns includes a second bonding surface facing the main surface, and a first area of the first bonding surface and a second area of the second bonding surface are different, and
wherein, among the plurality of first conductive columns and the plurality of second conductive columns, four second conductive columns are closest to four corners of the element body.

2. The semiconductor device of claim 1, wherein the second area is smaller than the first area.

3. The semiconductor device of claim 2, wherein the first area is 1.2 times or more the second area.

4. The semiconductor device of claim 1, wherein the element body includes a circuit, and
wherein each of the plurality of first conductive columns is electrically connected to the circuit.

5. The semiconductor device of claim 4, wherein at least one of the four second conductive columns is insulated from the circuit.

6. The semiconductor device of claim 2, wherein a dimension of each of the plurality of second conductive columns in the thickness direction is larger than a dimension of each of the plurality of first conductive columns in the thickness direction.

7. The semiconductor device of claim 1, wherein the first bonding surface is circular and the second bonding surface is circular.

8. The semiconductor device of claim 1, wherein the first bonding surface is elliptical and the second bonding surface is circular.

9. The semiconductor device of claim 1, further comprising:
a first bonding material interposed between the first bonding surface and the main surface; and
a second bonding material interposed between the second bonding surface and the main surface.

10. The semiconductor device of claim 9, wherein the first bonding material and the second bonding material include solder.

11. The semiconductor device of claim 1, wherein the conductor contains Cu.

12. The semiconductor device of claim 1, wherein the plurality of first conductive columns and the plurality of second conductive columns contain Cu.

13. The semiconductor device of claim 1, wherein the conductor is constituted by a lead.

14. The semiconductor device of claim 2, wherein the conductor includes a first lead, a second lead, and a third lead,
wherein each of the plurality of first conductive columns is bonded to the first lead, and
wherein, among the plurality of second conductive columns, at least one of the four second conductive columns is bonded to the first lead, and each of the other second conductive columns is bonded to the second lead or the third lead.

15. The semiconductor device of claim 14, wherein the element body includes a circuit,
wherein each of the plurality of first conductive columns is electrically connected to the circuit, and
wherein, among the four second conductive columns, the second conductive column bonded to the first lead is insulated from the circuit.

16. The semiconductor device of claim 1, further comprising: an insulating substrate,
wherein the conductor is a wiring formed on the insulating substrate.
